(19) United States
(12) Patent Application Publication
(10) Pub. No.: US 2018/0120697 A1
(43) Pub. Date: May 3, 2018

(54) ACTINIC RAY-SENSITIVE OR RADIATION-SENSITIVE COMPOSITION, AND ACTINIC RAY-SENSITIVE OR RADIATION-SENSITIVE COMPOSITION FILM USING THE COMPOSITION

(71) Applicant: FUJIFILM Corporation, Tokyo (JP)

(72) Inventors: Toru FUJIMORI, Haibara-gun (JP); Toru TSUCHIHASHI, Haibara-gun (JP)

(73) Assignee: FUJIFILM Corporation, Tokyo (JP)

(21) Appl. No.: 15/854,780

(22) Filed: Dec. 27, 2017

Related U.S. Application Data
(63) Continuation of application No. PCT/JP2016/067534, filed on Jun. 13, 2016.

(30) Foreign Application Priority Data
Jul. 29, 2015 (JP) 2015-149104

(51) Int. Cl. G03F 7/004

(52) U.S. Cl. CPC G03F 7/0044

(57) ABSTRACT

An object of the present invention is to provide an actinic ray-sensitive or radiation-sensitive composition which has excellent heat stability and makes it possible to achieve high sensitivity and good roughness characteristics. The actinic ray-sensitive or radiation-sensitive composition according to the present invention contains (A) a compound in which in an organic/inorganic composite composition containing a metal or metalloid element, the aggregated domain size of the metal or metalloid element is 1 to 5 nm, and 1.2 to 2.0 mol times of a carboxylic acid and/or a carboxylic acid derivative with respect to the metal or metalloid element exists to form a coordinated structure; (B) a compound (Q) capable of generating an acid upon irradiation with actinic rays or radiation; and (C) an organic solvent.

### CROSS-REFERENCE TO RELATED APPLICATIONS

This application is a Continuation of PCT International Application No. PCT/JP2016/067534 filed on Jun. 13, 2016, which claims priority under 35 U.S.C. § 119(a) to Japanese Patent Application No. 2015-149104 filed on Jul. 29, 2015. The above application is hereby expressly incorporated by reference, in its entirety, into the present application.

### BACKGROUND OF THE INVENTION

### 1. Field of the Invention

The present invention relates to an actinic ray-sensitive or radiation-sensitive composition and an actinic ray-sensitive or radiation-sensitive composition film using the composition. The present invention relates to a composition and a film, each of which is suitably used in an ultramicrolithography process applicable to a process for manufacturing a super-LSI or a high-capacity microchip, a process for fabricating a nanoimprint mold, a process for producing a high-density information recording medium, or the like, and other photofabrication processes, for example. More specifically, the present invention relates to a composition and a film, each of which is suitably used in microfabrication of a semiconductor element by electron beams or soft X-rays such as EUV light.

### 2. Description of the Related Art

In the microfabrication by lithography, formation of an ultrafine pattern on the order of tens of nanometers recently being demanded as higher integration for integrated circuits has been realized. In accordance with such a demand, a tendency that exposure wavelength becomes shorter is observed, as in transitions, for example, from g-lines to i-lines and further to a KrF excimer laser light. Moreover, at present, a development of lithography using electron beams, X-rays, or EUV light, in addition to the excimer laser light, is in progress.

This lithography using electron beams, X-rays, or EUV light is positioned as the next-generation or next-next-generation pattern forming technology, and a resist composition having high sensitivity and high resolution is desired.

In particular, it is a highly important task to attain high sensitivity in order to shorten a wafer-treating time, but if it is attempted to attain high sensitivity, a resolving power represented by a pattern profile or a critical resolution line width is lowered, and thus, development of a resist composition simultaneously satisfying these characteristics is strongly desired. In particular, high sensitivity is in a trade-off relationship with a high resolution or a good pattern profile, and thus, how to satisfy all of these properties simultaneously is very important.

The actinic ray-sensitive or radiation-sensitive compositions are generally classified into those with a “positive tone” in which a pattern is formed by making an exposed area soluble in an alkali developer through exposure by irradiation with radiation, using a resin sparingly soluble or insoluble in the alkali developer, and those with a “negative tone” in which a pattern is formed by making an exposed area sparingly soluble or insoluble in an alkali developer through exposure by irradiation with radiation, using a resin soluble in the alkali developer.

As an actinic ray-sensitive or radiation-sensitive resin composition which is appropriate for such a lithography process using electron beams, X-rays, or EUV light, a chemical amplification-type positive tone resist composition using an acid catalyst reaction has been mainly investigated from the viewpoint of high sensitivity, and a chemical amplification-type positive tone resist composition formed of a phenolic resin (hereinafter abbreviated as a phenolic acid-decomposable resin) having a property of being insoluble or sparingly soluble in an alkali developer and becoming soluble in the alkali developer by the action of an acid, and an acid generator as main components has been effectively used.

On the other hand, in the manufacture of semiconductor elements or the like, formation of patterns having various profiles such as lines, trenches, and holes has been required. In order to meet the requirements for formation of patterns having various profiles, development of not only a positive tone actinic ray-sensitive or radiation-sensitive resin composition but also a negative tone actinic ray-sensitive or radiation-sensitive resin composition has been made, and for example, the formation of a fine pattern having a line width of 50 nm or less requires lowered resolving power and further improving pattern profiles.

In order to solve such the problems, a method for developing an acid-decomposable resin using an organic developer other than an alkali developer has also been proposed (see, for example, JP2008-292975A).

Furthermore, a system in which materials referred to as nano-particles, instead of a resin, is used in a composition (see, for example, US20110039105A1). These materials are proposed as a system which is expected to attain higher sensitivity than that of a chemical amplification type resist. However, the materials have problems, for example, in that they cannot be stably handled and a film becomes insoluble in a developer in a heat drying treatment (prebaking treatment) after application, which is usually carried out in evaluation of a resist, and thus, a pattern cannot be formed. In addition, in micro regions with a line width of 50 nm or less, it is required to simultaneously satisfy high sensitivity, high resolving power, and high line width roughness (LWR) performance at a higher level.

Examples of related art include JP1993-232706A (JP-H05-232706A).

### SUMMARY OF THE INVENTION

An object of the present invention is to provide an actinic ray-sensitive or radiation-sensitive composition which has excellent heat stability and makes it possible to achieve high sensitivity and good roughness characteristics.

The present inventors have conducted extensive studies in order to accomplish the object, and as a result, the inventions exemplified below have been completed.

[1] An actinic ray-sensitive or radiation-sensitive composition comprising:

(A) a compound in which in an organic/inorganic composite composition containing a metal or metalloid element, the aggregated domain size of the metal or metalloid element is 1 to 5 nm, and 1.2 to 2.0 mol times of a carboxylic acid and/or a carboxylic acid derivative with respect to the metal or metalloid element exists, and forms a coordinated structure;

(B) a compound capable of generating an acid upon irradiation with actinic rays or radiation; and

(C) an organic solvent.

[2] The composition as described in [1], which is used for pattern formation by EUV exposure.

[3] The composition as described in [1], which is used for pattern formation by irradiation with electron beams or X-rays.

According to the present invention, it is possible to provide an actinic ray-sensitive or radiation-sensitive composition which can make it possible to attain high sensitivity and good roughness characteristics, and an actinic ray-sensitive or radiation-sensitive composition film using the same.

It is possible to attain remarkably high sensitivity, in particular, as compared with chemical amplification type resists in the related art. Further, heat stability and storage stability are excellent, as compared with nano-particles known in the related art, and therefore, it is possible to perform a heat treatment after application, which has been difficult to apply in the related art, and thus to perform good pattern formation.

### BRIEF DESCRIPTION OF THE DRAWINGS

FIG. 1 shows the particle size distribution of ZR-E.

FIG. 2 shows the infrared absorption spectrum (ATR method) of a film formed using each of the composite compositions.

FIG. 3 shows the infrared absorption spectrum (ATR method) of a film formed using each of the composite compositions.

### DESCRIPTION OF THE PREFERRED EMBODIMENTS

Hereinafter, the embodiments of the present invention will be described in detail.

Moreover, in a case where a group and an atomic group as used herein are denoted without specifying whether they are substituted or unsubstituted, the group and the atomic group are intended to encompass both a group and an atomic group having no substituent, and a group and an atomic group having a substituent. For example, an “alkyl group” denoted without specifying whether it is substituted or unsubstituted is intended to encompass not only an alkyl group having no substituent (unsubstituted alkyl group), but also an alkyl group having a substituent (substituted alkyl group).

Furthermore, “actinic rays” or “radiation” as used herein means, for example, a bright line spectrum of a mercury lamp, far ultraviolet rays represented by an excimer laser, soft X-rays such as extreme ultraviolet (EUV) rays, X-rays, or electron beams (EB). “Light” means actinic rays or radiation. “Exposure” means not only light irradiation by a mercury lamp, far ultraviolet rays, X-rays, EUV rays, or the like, but also writing by particle rays such as electron beams and ion beams.

The actinic ray-sensitive or radiation-sensitive composition according to the present invention includes (A) a compound in which in an organic/inorganic composite composition containing a metal or metalloid element, the aggregated domain size of the metal or metalloid element is 1 to 5 nm, and 1.2 to 2.0 mol times of a carboxylic acid and/or a carboxylic acid derivative with respect to the metal or metalloid element exists to form a coordinated structure, (B) a compound (hereinafter also referred to as an acid generator or compound (Q)) capable of generating an acid upon irradiation with actinic rays or radiation, and (C) an organic solvent.

The present inventors have found that by using a composition containing a hybrid sol-gel compound with an organic substance having a metal or metalloid element with a specific structure obtained by a specific synthesis method, it is possible to accomplish characteristics with excellent heat stability and storage stability, as well as high sensitivity and good roughness. In particular, they have found that remarkable effects in terms of heat stability and high sensitivity are expressed.

Hereinafter, the respective components described above will be sequentially described.

Many hydroxyl groups are usually present on the outermost surface of the metal or metalloid oxide. If the oxide size is smaller, self-cohesive force becomes stronger due to the effect of the hydroxyl groups on the surface, and it is very difficult to disintegrate aggregates once formed. On the other hand, in a technique using a metal alkoxide as a starting raw material, represented by a sol-gel method, some alkoxyl groups remain in the formed substances. A condensation reaction caused by the reaction of the residual alkoxyl groups with moisture in the atmosphere or the hydroxyl groups present in the formed substances can progress, thereby obtaining a cured product.

In order to improve the roughness characteristics of a fine line width, it is essential to reduce the size of a metal or metalloid oxide which serves as a core, and it is necessary to set the aggregated domain size to 1 to 5 nm. At this time, it becomes a state where an aggregate or a cured body is easily formed as described above.

The organic/inorganic composite composition of the present invention is formed of an inorganic domain including a metal or metalloid oxide formed by a polycondensation reaction, and the alkoxyl group or the hydroxyl group is inactivated by forming a coordinated structure with a carboxylic acid and/or a carboxylic acid derivative.

In order to impart solubility for application as a resist, the amount of the coexisting carboxylic acid and/or carboxylic acid derivative is preferably 1.2 to 2.0 mol times, more preferably 1.4 times to 2.0 mol times, and still more preferably 1.5 times to 2.0 mol times, with respect to the metal or metalloid element. In a case where the amount is less than 1.2 times, alkoxyl groups remain in a compound thus formed, and as a result, condensation progresses by a temporal reaction, and thus, solubility cannot be imparted. Further, the condensation also progresses in a heat drying treatment (prebaking) after application, and thus solubility is lost. On the other hand, in a case where the amount is 2.0 mol times or more, the unreacted carboxylic acid and/or carboxylic acid derivative remains in the film, and its amount is thus sufficient. However, if the carboxylic acid and/or carboxylic acid derivative is added in the amount or more, it remains in a free state, causing a concern that pattern formation may be inhibited in some cases.

The coexisting carboxylic acid and/or carboxylic acid derivative is not particularly limited. For example, examples of the saturated aliphatic acid include acetic acid, propanoic acid, butyric acid, valeric acid, caproic acid, enanthic acid, caprylic acid, cyclopropanecarboxylic acid, cyclobutanecarboxylic acid, cyclopentanecarboxylic acid, and cyclohexanecarboxylic acid. Examples of the unsaturated aliphatic acid include acrylic acid, methacrylic acid, cyclopropenecarboxylic acid, cyclopentenecarboxylic acid, and cyclohexenecarboxylic acid. Examples of the aromatic acid include benzoic acid, naphthoic acid, anthracenecarboxylic acid, and vinylbenzoic acid.

[2] Photoacid Generator

The composition according to the present invention contains a photoacid generator.

The photoacid generator may be low-molecular-weight compound or a high-molecular-weight compound, and among these, a compound capable of generating organic acids such as sulfonic acid, bis(alkylsulfonyl)imide, and tris(alkylsulfonyl)methide is preferable.

Examples of the low-molecular-weight acid generator include compounds represented by General Formulae (ZI), (ZII), and (ZIII).

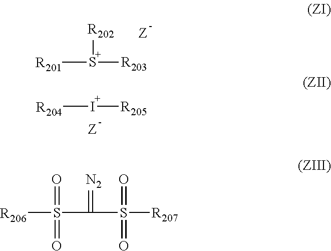

In General Formula (ZI),

R₂₀₁, R₂₀₂, and R₂₀₃ each independently represent an organic group.

The number of carbon atoms in the organic group as R₂₀₁, R₂₀₂, and R₂₀₃ is generally 1 to 30, and preferably 1 to 20.

In addition, two of R₂₀₁, . . . , or R₂₀₃ may be bonded to each other to form a ring structure, and the ring may contain therein an oxygen atom, a sulfur atom, an ester bond, an amide bond, or a carbonyl group. Examples of the group formed by the bonding of two of R₂₀₁, . . . , or R₂₀₃ include an alkylene group (for example, a butylene group and a pentylene group).

Z⁻ represents a non-nucleophilic anion (anion having an extremely low ability of causing a nucleophilic reaction).

Examples of the non-nucleophilic anion include a sulfonate anion (an aliphatic sulfonate anion, an aromatic sulfonate anion, a camphor sulfonate anion, and the like), a carboxylate anion (an aliphatic carboxylate anion, an aromatic carboxylate anion, an aralkyl carboxylate anion, and the like), a sulfonylimide anion, a bis(alkylsulfonyl)imide anion, and a tris(alkylsulfonyl)methide anion.

The aliphatic moiety in the aliphatic sulfonate anion and aliphatic carboxylate anion may be an alkyl group or a cycloalkyl group, and preferred examples thereof include a linear or branched alkyl group having 1 to 30 carbon atoms and a cycloalkyl group having 3 to 30 carbon atoms.

Preferred examples of the aromatic group in the aromatic sulfonate anion and the aromatic carboxylate anion include an aryl group having 6 to 14 carbon atoms, such as a phenyl group, a tolyl group, and a naphthyl group.

The alkyl group, the cycloalkyl group, and the aryl group exemplified above may have a substituent. Specific examples of the substituent include a nitro group, a halogen atom such as a fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), an alkoxycarbonyloxy group (preferably having 2 to 7 carbon atoms), an alkylthio group (preferably having 1 to 15 carbon atoms), an alkylsulfonyl group (preferably having 1 to 15 carbon atoms), an alkyliminosulfonyl group (preferably having 2 to 15 carbon atoms), an aryloxysulfonyl group (preferably having 6 to 20 carbon atoms), an alkylaryloxysulfonyl group (preferably having 7 to 20 carbon atoms), a cycloalkylaryloxysulfonyl group (preferably having 10 to 20 carbon atoms), an alkyloxyalkyloxy group (preferably having 5 to 20 carbon atoms), and a cycloalkylalkyloxyalkyloxy group (preferably having 8 to 20 carbon atoms). Other examples of the aryl group or the ring structure contained in each of the groups include an alkyl group (preferably having 1 to 15 carbon atoms) as a substituent.

Preferred examples of the aralkyl group in the aralkyl carboxylate anion include an aralkyl group having 6 to 12 carbon atoms, such as a benzyl group, a phenethyl group, a naphthylmethyl group, a naphthylethyl group, and a naphthylbutyl group.

Examples of the sulfonylimide anion include a saccharin anion.

The alkyl group in the bis(alkylsulfonyl)imide anion and the tris(alkylsulfonyl)methide anion is preferably an alkyl group having 1 to 5 carbon atoms. Examples of the substituent of this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with the fluorine atom and the fluorine atom-substituted alkyl group being preferable.

Furthermore, the alkyl groups in the bis(alkylsulfonyl)imide anion may be bonded to each other to form a ring structure. Thus, the acid strength is increased.

Other examples of the non-nucleophilic anion include fluorinated phosphorus (for example, PF₆⁻), fluorinated boron (for example, BF₄⁻), and fluorinated antimony (for example, SbF₆⁻).

The non-nucleophilic anion is preferably an aliphatic sulfonate anion in which at least at the a-position of the sulfonic acid is substituted with a fluorine atom, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion (still more preferably having 4 to 8 carbon atoms) or a fluorine atom-containing benzenesulfonate anion, and still more preferably a nonafluorobutanesulfonate anion, a perfluorooctanesulfonate anion, a pentafluorobenzenesulfonate anion, or a 3,5-bis(trifluoromethyl)benzenesulfonate anion.

From the viewpoint of the acid strength, the pKa of the acid generated is preferably -1 or less for improvement of the sensitivity.

Moreover, preferred aspects of the non-nucleophilic anion also include an anion represented by General Formula (AN1).

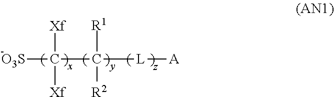

In the formula,

Xf's each independently represent a fluorine atom or an alkyl group substituted with at least one fluorine atom.

R¹ and R² each independently represent a group selected from a hydrogen atom, a fluorine atom, an alkyl group, and an alkyl group having at least one fluorine atom, and in a case where a plurality of R¹'s or R²'s are present, they may be the same as or different from each other.

L represents a single bond or a divalent linking group, and in a case where a plurality of L's are present they may be the same as or different from each other.

A represents a cyclic structure.

x represents an integer of 1 to 20, y represents an integer of 0 to 10, and z represents an integer of 0 to 10.

General Formula (AN1) will be described in more detail.

The alkyl group in the fluorine atom-substituted alkyl group of Xf is preferably an alkyl group having 1 to 10 carbon atoms, and more preferably an alkyl group having 1 to 4 carbon atoms. Further, the fluorine atom-substituted alkyl group of Xf is preferably a perfluoroalkyl group.

Xf is preferably a fluorine atom or a perfluoroalkyl group having 1 to 4 carbon atoms. Specific examples of Xf include a fluorine atom, CF₃, C₂F₅, C₃F₇, C₄F₉, CH₂CF3, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉, and among these, a fluorine atom and CF₃ are preferable.

The alkyl group in each of R¹ and R², and the alkyl group in the alkyl group substituted with at least one fluorine atom are each preferably an alkyl group having 1 to 4 carbon atoms.

x is preferably 1 to 10, and more preferably 1 to 5.

y is preferably 0 to 4, and more preferably 0.

z is preferably 0 to 5, and more preferably 0 to 3.

The divalent linking group of L is not particularly limited, and examples thereof include —COO—, —OCO—, —CO—, —O—, —S—, —SO—, —SO₂—, an alkylene group, a cycloalkylene group, and an alkenylene group. Among these, —COO—, —OCO—, —CO—, or —O— is preferable, and —COO— or —OCO— is more preferable.

The group having a cyclic structure of A is not particularly limited as long as it has a cyclic structure, and examples thereof include an alicyclic group, an aryl group, and a group having a heterocyclic structure (including not only a group having a heterocyclic structure having aromaticity but also a group having a heterocyclic structure having no aromaticity).

The alicyclic group may be monocyclic or polycyclic, and is preferably a monocyclic cycloalkyl group such as a cyclopentyl group, a cyclohexyl group, and a cyclooctyl group, or a polycyclic cycloalkyl group such as a norbornyl group, a tricyclodecanyl group, a tetracyclodecanyl group, a tetracyclododecanyl group, and an adamantyl group. Among those, an alicyclic group having a bulky structure having 7 or more carbon atoms, such as a norbornyl group, a tricyclodecanyl group, a tetracyclodecanyl group, a tetracyclododecanyl group, and an adamantyl group, is preferable from the viewpoint of improvement of MEEF since the diffusion in the film in a heating step after exposure can be suppressed.

Examples of the aryl group include a benzene ring, a naphthalene ring, a phenanthrene ring, and an anthracene ring.

Examples of the group having a heterocyclic structure include a furan ring, a thiophene ring, a benzofuran ring, a benzothiophene ring, a dibenzofuran ring, a dibenzothiophene ring, and a pyridine ring. Among these, a furan ring, a thiophene ring, or a pyridine ring is preferable.

The group having a cyclic structure may have a substituent, and examples of the substituent include an alkyl group (which may be in any one of linear, branched, and cyclic forms; and preferably has 1 to 12 carbon atoms), an aryl group (preferably having 6 to 14 carbon atoms), a hydroxy group, an alkoxy group, an ester group, an amido group, a urethane group, a ureido group, a thioether group, a sulfonamido group, and a sulfonic ester group.

Examples of the organic group of R₂₀₁, R₂₀₂, and R₂₀₃ include an aryl group, an alkyl group, and a cycloalkyl group.

It is preferable that at least one of R₂₀₁, R₂₀₂, or R₂₀₃ is an aryl group, and it is more preferable that all of R₂₀₁, R₂₀₂, and R₂₀₃ are an aryl group. The aryl group can also be a heteroaryl group such as an indole residue and a pyrrole residue, other than a phenyl group, a naphthyl group, and the like. Preferred examples of the alkyl group and the cycloalkyl group of each of R₂₀₁ to R₂₀₃ include a linear or branched alkyl group having 1 to 10 carbon atoms and a cycloalkyl group having 3 to 10 carbon atoms. More preferred examples of the alkyl group include a methyl group, an ethyl group, an n-propyl group, an i-propyl group, and an n-butyl group. More preferred examples of the cycloalkyl group include a cyclopropyl group, a cyclobutyl group, a cyclopentyl group, a cyclohexyl group, and a cycloheptyl group. These groups may further have a substituent, and examples of the substituent include, but are not limited to, a nitro group, a halogen atom such as fluorine atom, a carboxyl group, a hydroxyl group, an amino group, a cyano group, an alkoxy group (preferably having 1 to 15 carbon atoms), a cycloalkyl group (preferably having 3 to 15 carbon atoms), an aryl group (preferably having 6 to 14 carbon atoms), an alkoxycarbonyl group (preferably having 2 to 7 carbon atoms), an acyl group (preferably having 2 to 12 carbon atoms), and an alkoxycarbonyloxy group (preferably having 2 to 7 carbon atoms).

Moreover, in a case where two of R₂₀₁ to R₂₀₃ are bonded to each other to form a ring structure, the ring structure is preferably a structure represented by General Formula (Al).

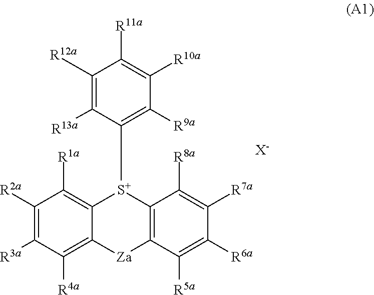

In General Formula (A1),

R^{1a} to R^{13a} each independently represent a hydrogen atom or a substituent.

It is preferable that one to three of R^{1a} to R^{13a} are not a hydrogen atom; and it is more preferable that any one of R^{9a} to R^{13a} is not a hydrogen atom.

Za represents a single bond or a divalent linking group.

X⁻ has the same definition as Z⁻ in General Formula (ZI).

Specific examples of R^{1a} to R^{13a} in a case where they are not a hydrogen atom include a halogen atom, a linear, branched, or cyclic alkyl group, an alkenyl group, an alkynyl group, an aryl group, a heterocyclic group, a cyano group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, alkyl- and arylsulfonylamino groups, a mercapto group, an alkylthio group, an arylthio group, a heterocyclic thio group, a sulfamoyl group, a sulfo group, alkyl- and arylsulfinyl groups, alkyl- and arylsulfonyl groups, an acyl group, an aryloxycarbonyl group, an alkoxycarbonyl group, a carbamoyl group, aryl- and heterocyclic azo groups, an imido group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents.

In a case where R^{1a} to R^{13a} are not a hydrogen atom, they are each preferably a linear, branched, or cyclic alkyl group substituted with a hydroxyl group.

Examples of the divalent linking group of Za include an alkylene group, an arylene group, a carbonyl group, a sulfonyl group, a carbonyloxy group, a carbonylamino group, a sulfonylamido group, an ether bond, a thioether bond, an amino group, a disulfide group, —(CH₂)ₙ—CO—, —(CH₂)ₙ—SO₂—, —CH═CH—, an aminocarbonylamino group, and an aminosulfonylamino group (n is an integer of 1 to 3).

Incidentally, the preferred structures in a case where at least one of R₂₀₁, R_{202,} or R₂₀₃ is not an aryl group include a cation structure such as the compounds described in paragraphs 0047 and 0048 of JP2004-233661A and paragraphs 0040 to 0046 of JP2003-35948A, the compounds exemplified as Formulae (I-1) to (I-70) in the specification of US2003/0224288A1, and the compounds exemplified as Formulae (IA-1) to (IA-54) and Formulae (IB-1) to (IB-24) in the specification of US2003/0077540A1.

In General Formulae (ZII) and (ZIII),

R₂₀₄ to R₂₀₇ each independently represent an aryl group, an alkyl group, or a cycloalkyl group.

The aryl group, the alkyl group, and the cycloalkyl group of each of R₂₀₄ to R₂₀₇ are the same as those mentioned as the aryl group, the alkyl group, and the cycloalkyl group of each of R₂₀₁ to R₂₀₃ in the compound (ZI) described above.

The aryl group, the alkyl group, and the cycloalkyl group of each of R₂₀₄ to R₂₀₇ may have a substituent. Examples of the substituent include those of the substituent which may be substituted on the aryl group, the alkyl group, and the cycloalkyl group of each of R₂₀₁ to R₂₀₃ in the compound (ZI) described above.

Z⁻ represents a non-nucleophilic anion, and examples thereof include the same ones as the non-nucleophilic anions of Z⁻ in General Formula (ZI).

Other examples of the acid generator include compounds represented by General Formula (ZIV), (ZV), and (ZVI).

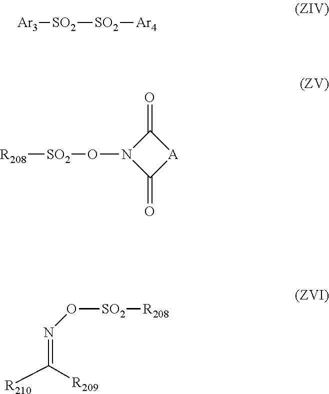

In General Formulae (ZIV) to (ZVI),

Ara and Ara each independently represent an aryl group. R₂₀₈, R₂₀₉, and R₂₁₀ each independently represent an alkyl group, a cycloalkyl group, or an aryl group.

A represents an alkylene group, an alkenylene group, or an arylene group.

Specific examples of the aryl group of each of Ar₃, Ar₄, R₂₀₈, R₂₀₉, and R₂₁₀ include the same ones as the specific examples of the aryl group of each of R₂₀₁, R₂₀₂, and R₂₀₃ in General Formula (ZI).

Specific examples of the alkyl group and the cycloalkyl group of each of R₂₀₈, R₂₀₉, and R₂₁₀ include the same ones as the specific examples of the alkyl group and the cycloalkyl group of each of R₂₀₁, R₂₀₂, and R₂₀₃ in General Formula (ZI).

Examples of the alkylene group of A include an alkylene group having 1 to 12 carbon atoms (for example, a methylene group, an ethylene group, a propylene group, an isopropylene group, a butylene group, and an isobutylene group); examples of the alkenylene group of A include an alkenylene group having 2 to 12 carbon atoms (for example, an ethenylene group, a propenylene group, and a butenylene group); and examples of the arylene group of A include an arylene group having 6 to 10 carbon atoms (for example, a phenylene group, a tolylene group, and a naphthylene group).

Among the acid generators, particularly preferred examples thereof are shown below.

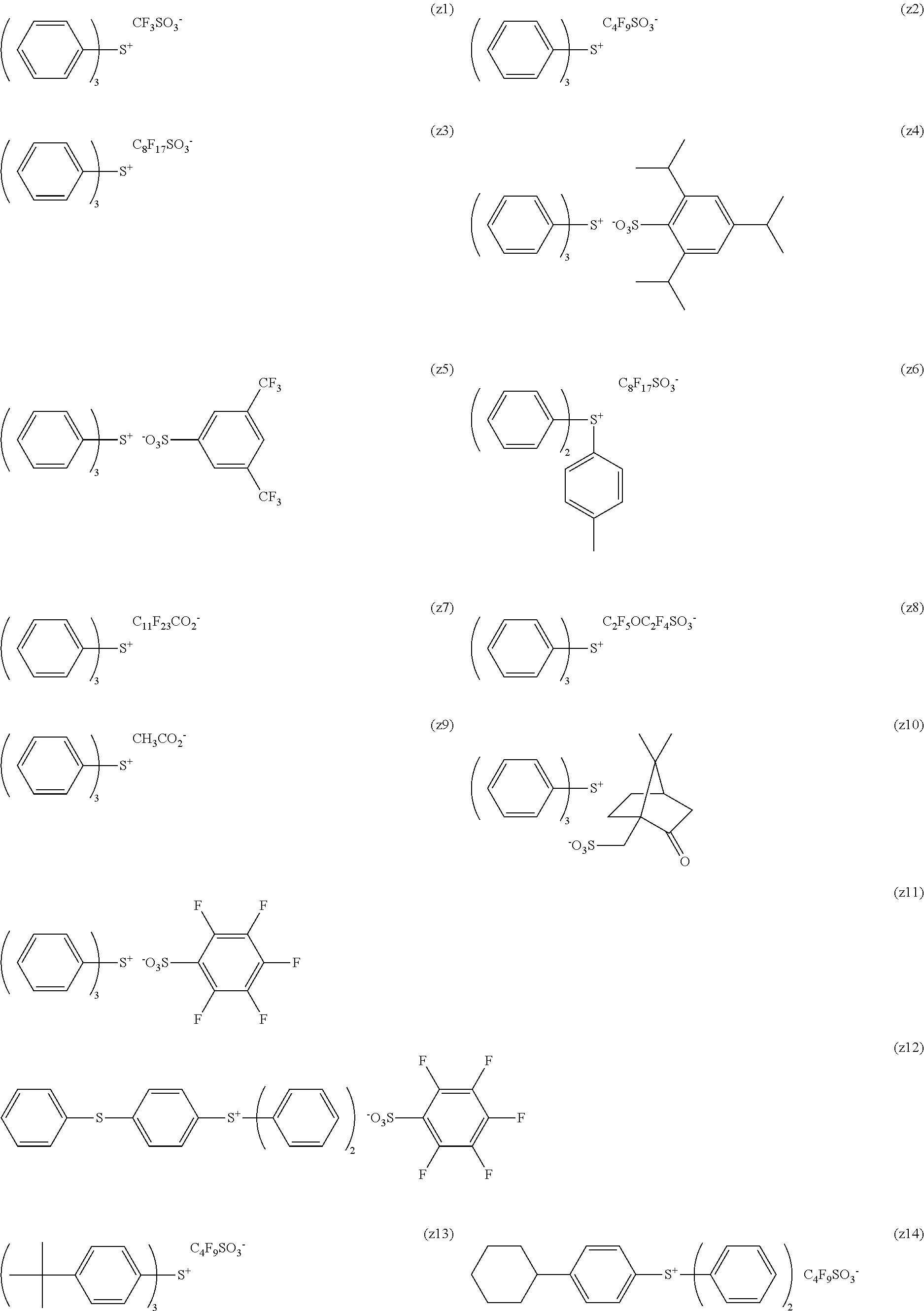

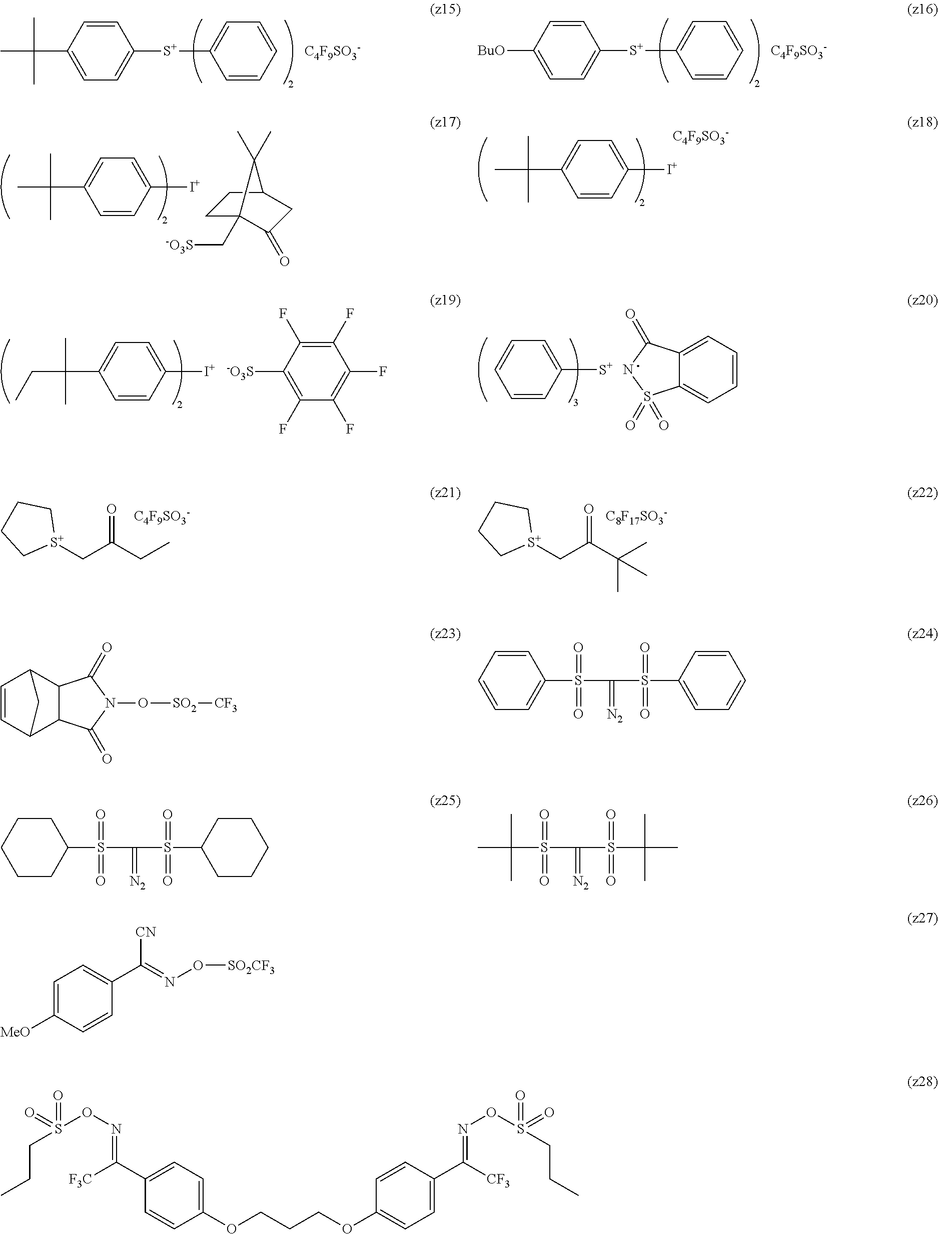

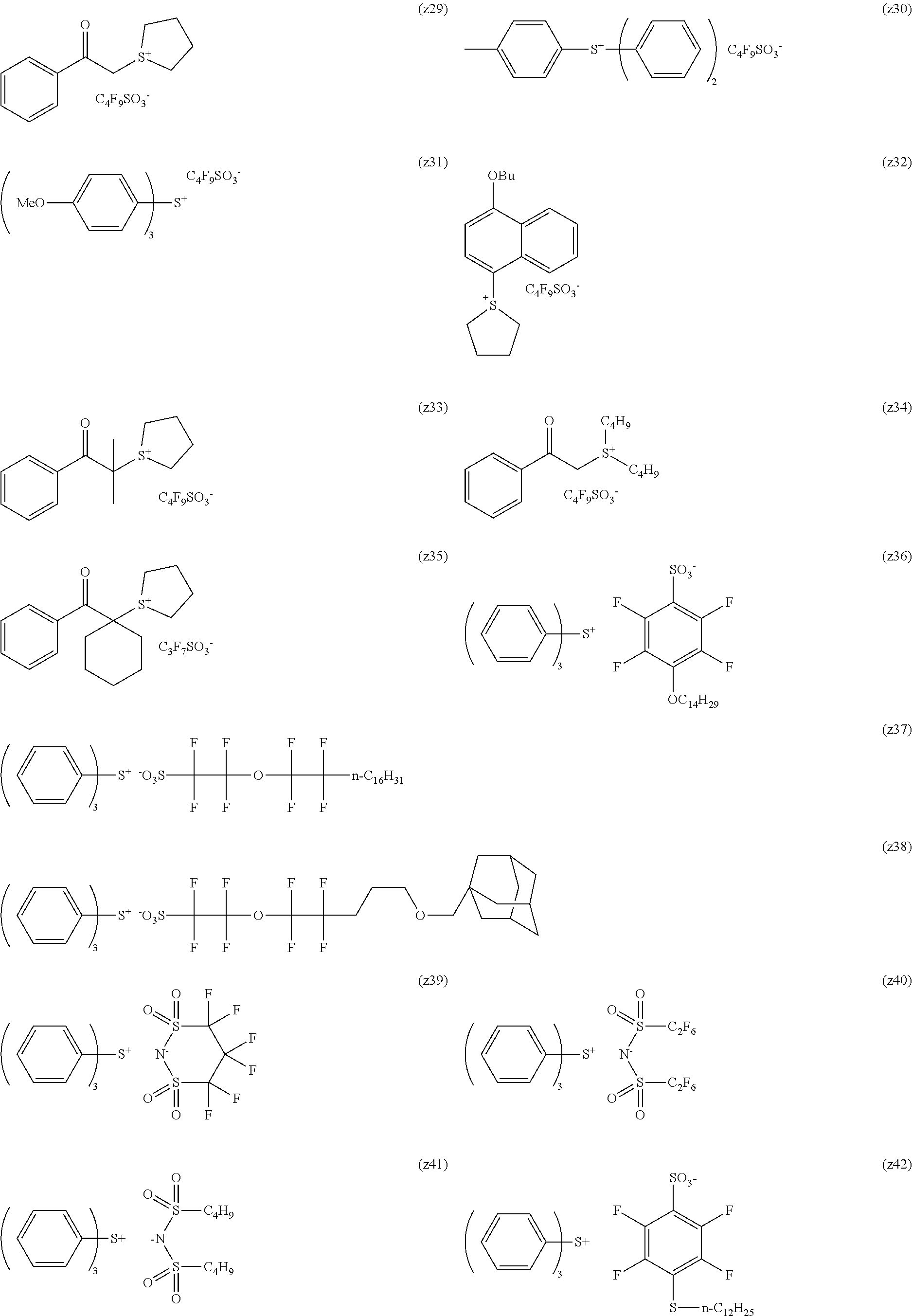

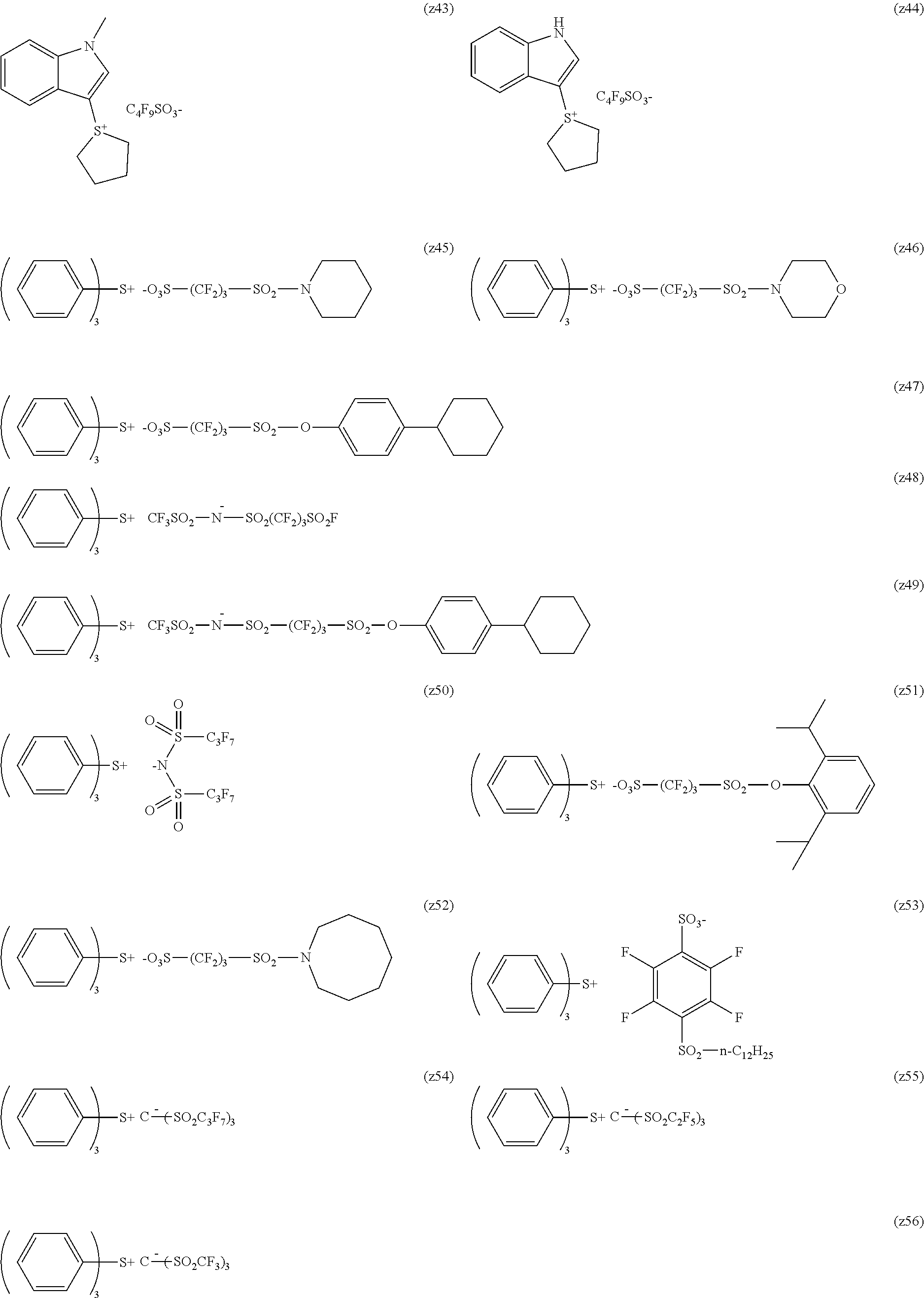

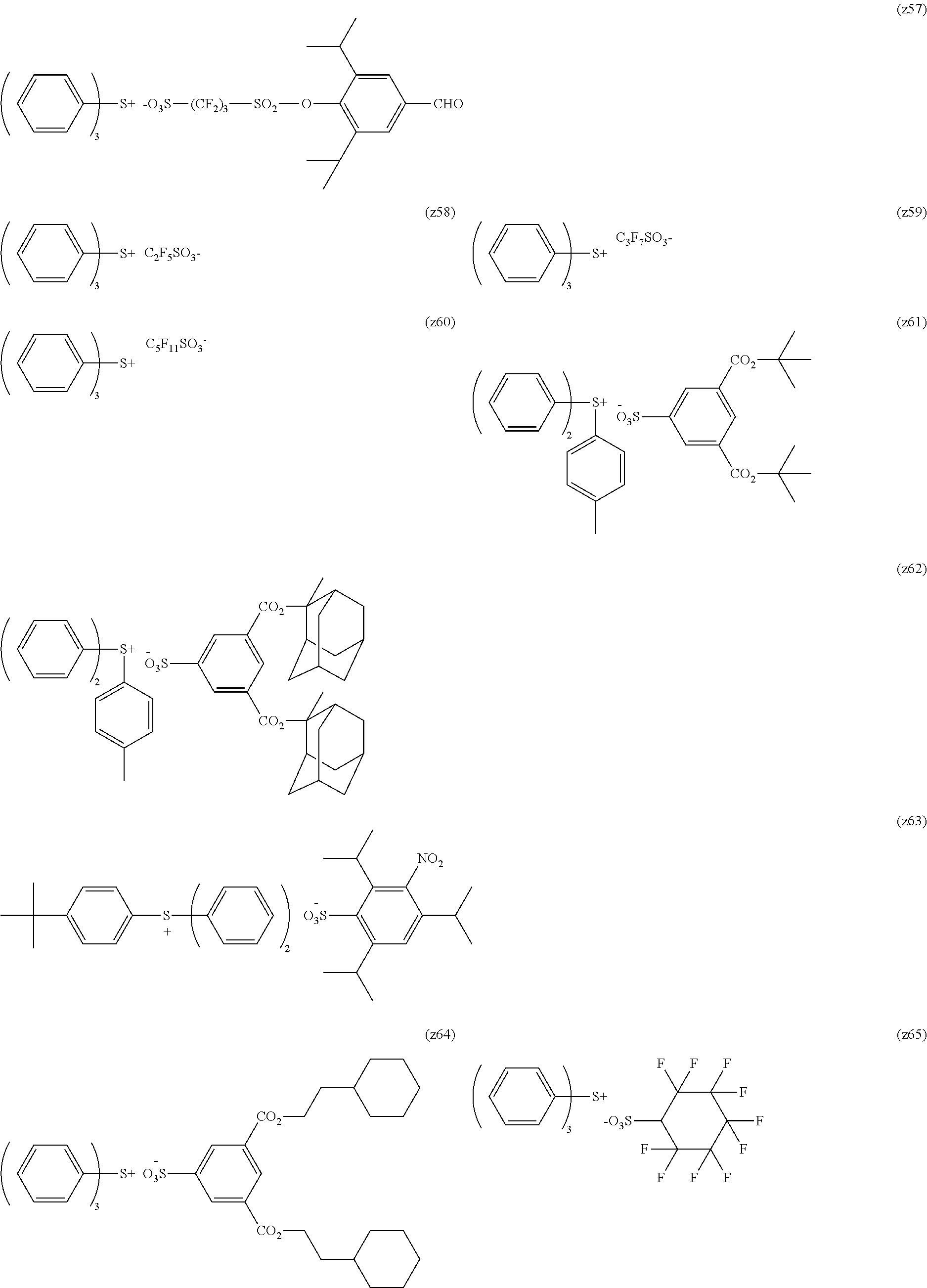

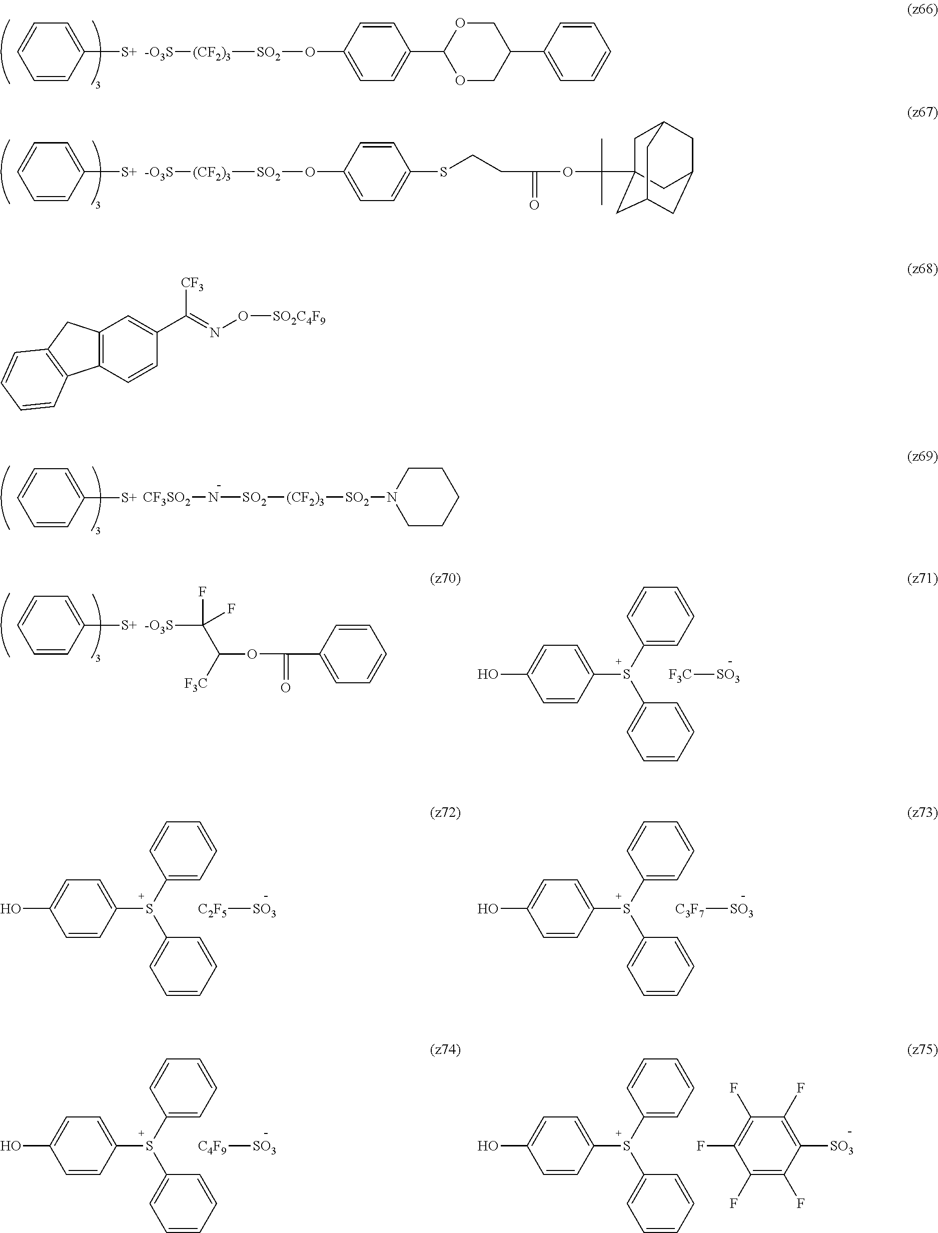

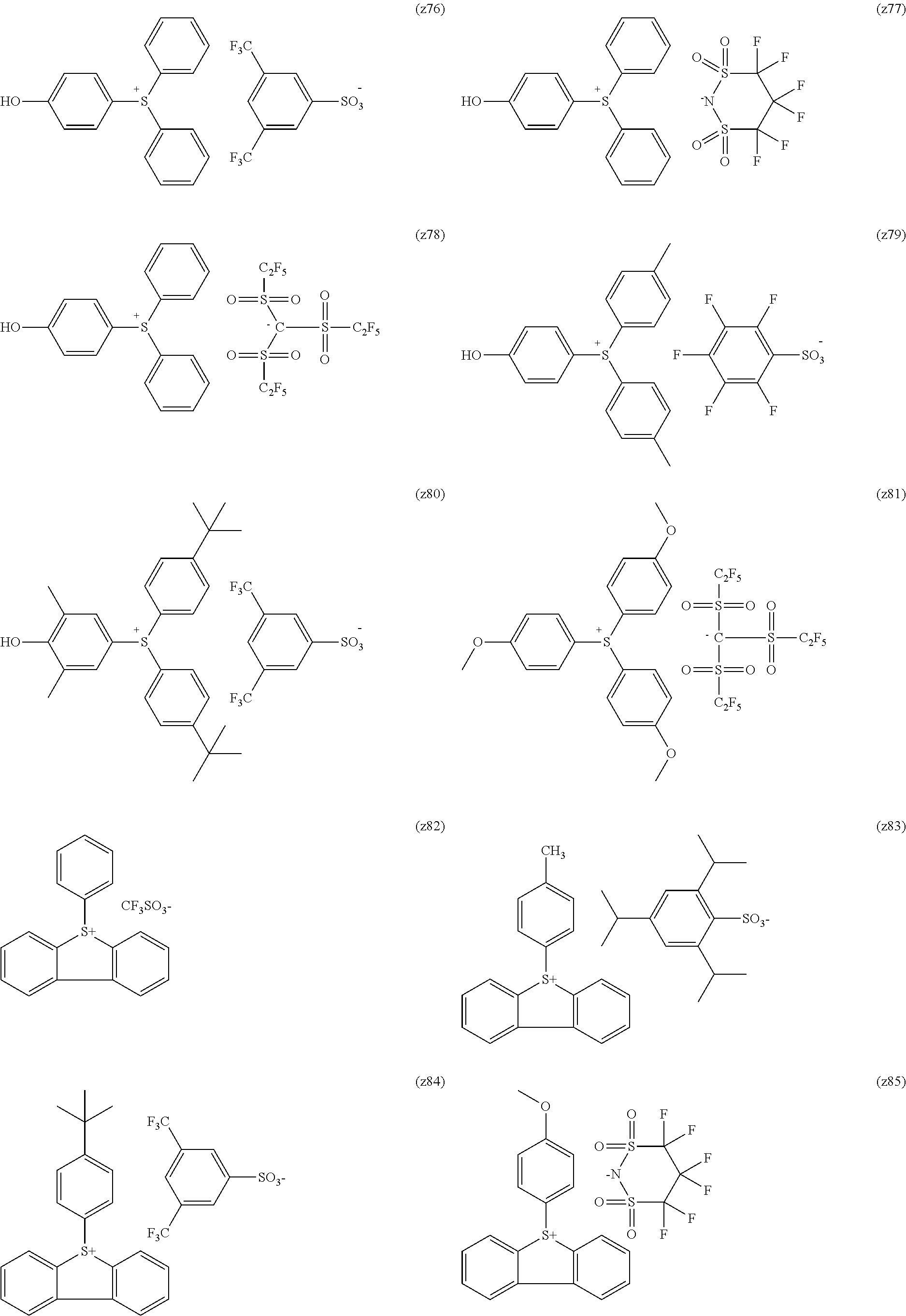

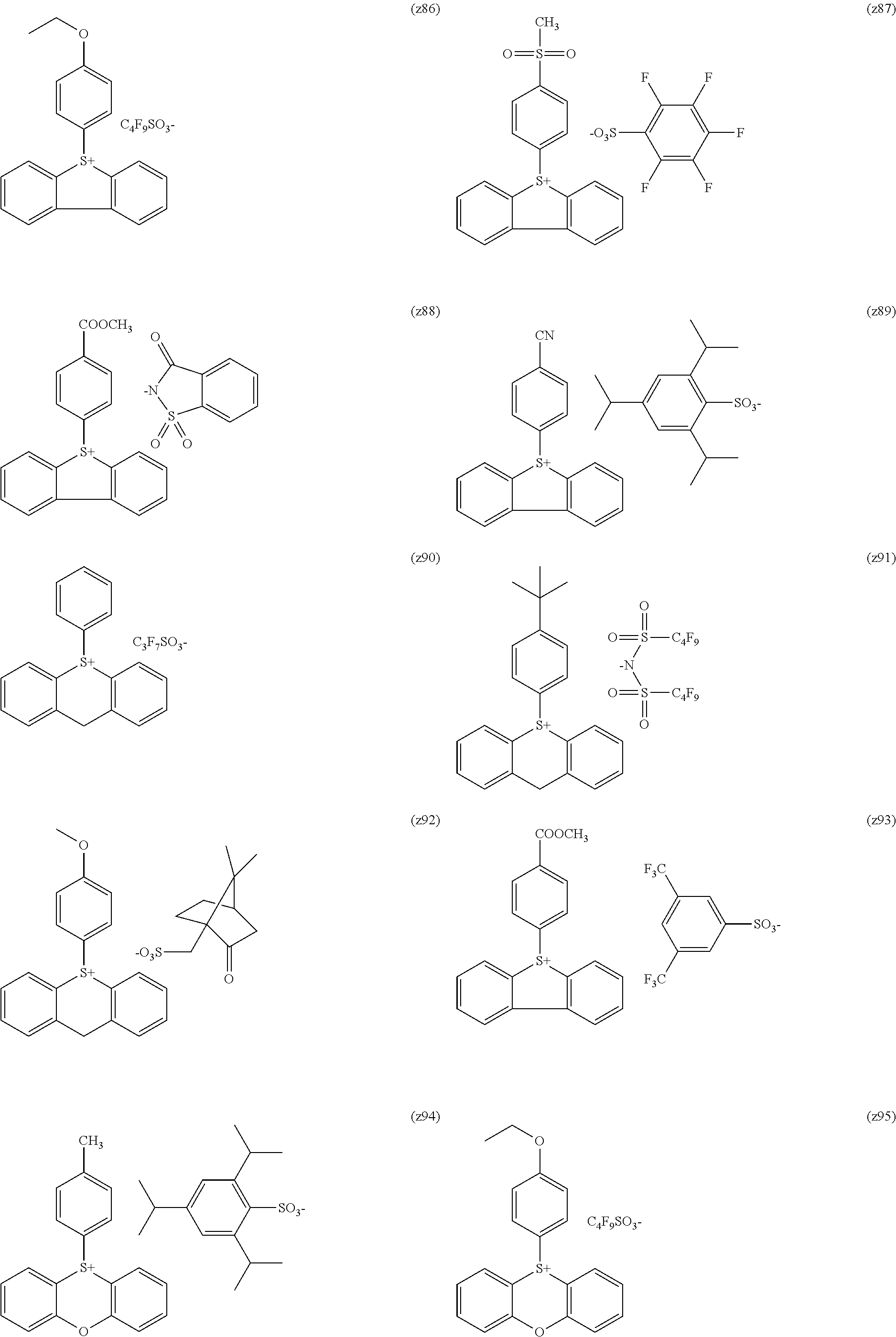

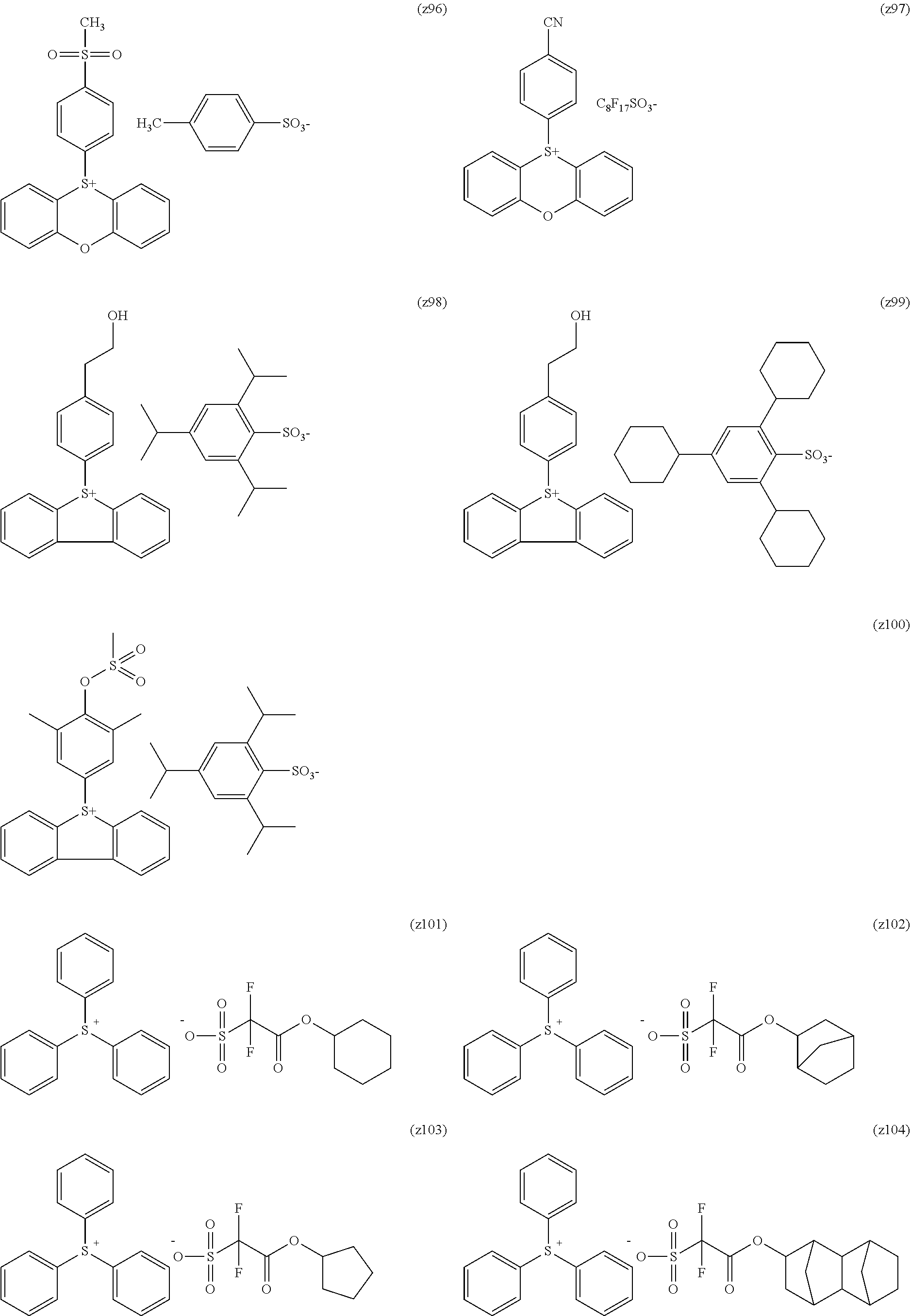

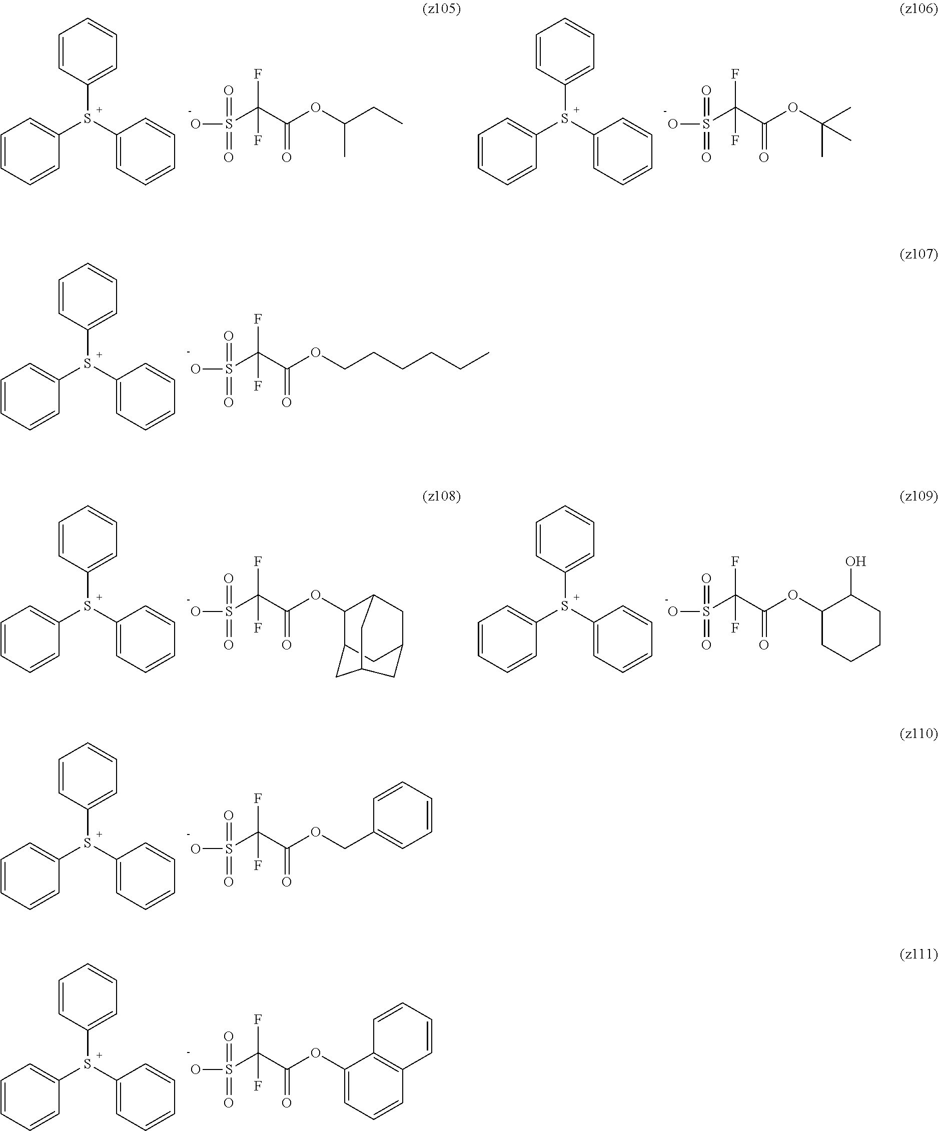

In a case of the low-molecular-weight acid generator, the content of the acid generator in the composition is preferably 0.01% to 50% by mass, more preferably 1% to 40% by mass, and still more preferably 2% to 30% by mass, with respect to the total solid content of the composition.

[4] Other Components

The composition according to the present invention may further contain other components.

For example, the composition according to the present invention preferably further contains a surfactant. As the surfactant, fluorine-based and/or silicone-based surfactants are preferable.

Examples of the surfactants corresponding thereto include MEGAFACE F177 and MEGAFACE R08 (manufactured by Dainippon Ink & Chemicals, Inc.), PF656 and PF6320 manufactured by OMNOVA Solutions Inc., TROYSOL S-366 (manufactured by Troy Chemical Corp.), FLORAD FC 430 (manufactured by Sumitomo 3M, Ltd.), and Polysiloxane Polymer KP-341 (manufactured by Shin-Etsu Chemical Co., Ltd.).

In addition, surfactants other than the fluorine-based and/or silicone-based surfactants can also be used. More specific examples thereof include polyoxyethylenealkyl ethers and polyoxyethylenealkylaryl ethers. In addition, examples of the usable surfactants include the surfactants described after paragraph [0273] in the specification of US2008/0248425A.

These surfactants may be used singly or in combination of two or more kinds thereof.

The amount of the surfactant to be used is preferably 0.0001% to 2% by mass, and more preferably 0.001% to 1% by mass, with respect to the total solid content of the composition.

The composition according to the present invention includes a (C) solvent. Examples of the solvent include organic solvents such as alkylene glycol monoalkyl ether carboxylate, alkylene glycol monoalkyl ether, alkyl lactate ester, alkyl alkoxypropionate, cyclic lactone, a monoketone compound which may have a ring, alkylene carbonate, alkyl alkoxyacetate, and alkyl pyruvate. In particular, a solvent having a standard boiling point of 150° C. or lower is preferable.

Preferred examples of the solvent include 2-heptanone, cyclopentanone, γ-butyrolactone, cyclohexanone, butyl acetate, ethyl lactate, ethylene glycol monoethyl ether acetate, propylene glycol monomethyl ether acetate, propylene glycol monomethyl ether, 3-ethylethoxy propionate, ethyl pyruvate, 2-ethoxyethyl acetate, 2-(2-ethoxyethoxy)ethyl acetate, and propylene carbonate. Particularly preferred examples of the solvent include propylene glycol monomethyl ether acetate and propylene glycol monomethyl ether.

In the present invention, the solvents may be used singly or in combination of two or more kinds thereof.

The amount of the solvent to be used in the total amount of the composition of the present invention can appropriately be adjusted depending on the film thickness or the like, but the solvent is generally prepared such that the concentration of the total solid content is 0.5% to 30% by mass, preferably 1.0% to 20% by mass, and more preferably 1.5% to 10% by mass.

<Pattern Forming Method>

Typically, the composition according to the present invention is applied onto a support such as a substrate to form a film. More specifically, formation of a resist film can be carried out by dissolving the respective components which will be described later, of the actinic ray-sensitive or radiation-sensitive resin composition, in a solvent, and as desired, filtering the solution through a filter and then applying the filtered solution on a support (substrate). The filter is preferably a polytetrafluoroethylene-, polyethylene-, or nylon-made filter having a pore size of 0.1 μm or less, more preferably 0.05 μm or less, and still more preferably 0.03 μm or less.

The thickness of this film is preferably 0.02 to 10.0 μm. As a method for applying the composition onto the substrate, spin coating is preferable and the rotation speed is preferably 1,000 to 3,000 rpm.

For example, the composition is applied onto a substrate (examples: a silicon/silicon dioxide-coated substrate and a silicon nitride-and-chromium-deposited quartz substrate) used for the manufacture of a precision integrated circuit element, or the like by an appropriate application method such as use of a spinner or a coater, and then dried (baked) to form an actinic ray-sensitive or radiation-sensitive film (hereinafter also referred to as a photosensitive film). An inorganic or organic antireflection film can be used in the underlayer. As the antireflection film, both of an inorganic film type such as titanium, titanium dioxide, titanium nitride, chromium oxide, carbon, and amorphous silicon, and an organic film type formed of a light absorbent and a polymer material can be used. In addition, as the organic antireflection film, a commercially available organic antireflection film such as DUV30 series or DUV-40 series manufactured by Brewer Science, Inc., AR-2, AR-3, or AR-5 manufactured by Shipley Company, L.L.C., or ARC series such as ARC29A manufactured by Nissan Chemical Industries, Ltd. can also be used. Further, a silicon hard mask or a spin on carbon can also be used, and a silicon hard mask can be coated on a silicon hard mask.

Then, the photosensitive film is irradiated with actinic rays or radiation, and as desired, baked (heated) and then developed. By performing the baking, it is possible to obtain a better pattern. Further, the baking temperature is preferably set to 70° C. to 150° C., and more preferably set to 80° C. to 130° C., from the viewpoints of sensitivity and stability.

Examples of the actinic rays or radiation include visible light, ultraviolet rays, far ultraviolet rays, X-rays, and electron beams. As the actinic rays or radiation, for example, those having a wavelength of 250 nm or less, in particular, those having a wavelength of 220 nm or less are more preferable. Examples of such actinic rays or radiation include KrF excimer laser (248 nm), ArF excimer laser (193 nm), F2 excimer laser (157 nm), X-rays, and electron beams. Preferred examples of the actinic rays or radiation include EUV rays and electron beams, and the actinic rays or radiation is particularly suitable for EUV rays.

Furthermore, upon irradiation with actinic rays or radiation, exposure with a filling of a liquid having a higher refractive index (pure water or the like) than that of air between a photosensitive film and a lens, that is, liquid immersion exposure may be carried out, whereby a resolution can be increased.

In the developing step, an alkali developer or a developer including an organic solvent is used. In a case of using the alkali developer, as the alkali developer for the composition of the present invention, an aqueous alkaline solution of, for example, inorganic alkalis such as sodium hydroxide, potassium hydroxide, sodium carbonate, sodium silicate, sodium metasilicate, and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide and tetraethylammonium hydroxide, and cyclic amines such as pyrrole and piperidine can be used.

Moreover, an appropriate amount of alcohols or a surfactant can also be added to the alkali developer before use. The alkali concentration of the alkali developer is usually 0.1% to 20% by mass. The pH of the alkali developer is usually 10.0 to 15.0.

In a case where development is carried out using the developer including an organic solvent, the vapor pressure (total vapor pressure in a case of a mixed solvent) of the developer is preferably 5 kPa or less, more preferably 3 kPa or less, and particularly preferably 2 kPa or less, at 20° C. By setting the vapor pressure of the organic solvent to 5 kPa or less, the evaporation of the developer on a substrate or in a development cup is suppressed, the temperature evenness within a wafer plane is improved, and the dimensional evenness within a wafer plane is thus enhanced.

As the organic solvent used in the developer, various organic solvents are widely used, and, for example, solvents such as an ester-based solvent, a ketone-based solvent, an alcohol-based solvent, an amide-based solvent, an ether-based solvent, and a hydrocarbon-based solvent can be used.

In the present invention, the ester-based solvent refers to a solvent having an ester group in the molecule, the ketone-based solvent refers to a solvent having a ketone group in the molecule, the alcohol-based solvent refers to a solvent having an alcoholic hydroxyl group in the molecule, the amide-based solvent refers to a solvent having an amido group in the molecule, and the ether-based solvent refers to a solvent having an ether bond in the molecule. Among these, a solvent having a plurality of functional groups described above per molecule may also be present, but in this case, it is assumed that the solvent also corresponds to any solvent species including a functional group which the solvent has. For example, it is assumed that diethylene glycol monomethyl ether also corresponds to either of the alcohol-based solvent and the ether-based solvent, in the above classification. In addition, the hydrocarbon-based solvent is a hydrocarbon solvent having no substituent.

In particular, a developer containing at least one kind of solvent selected from a ketone-based solvent, an ester-based solvent, an alcohol-based solvent, and an ether-based solvent is preferable.

Examples of the ester-based solvent include methyl acetate, ethyl acetate, butyl acetate, pentyl acetate, isopropyl acetate, amyl acetate, isoamyl acetate, ethyl methoxyacetate, ethyl ethoxyacetate, propylene glycol monomethyl ether acetate (PGMEA; also referred to as 1-methoxy-2-acetoxypropane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methyl cyclohexanone, phenyl acetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, and y-butyrolactone.

Examples of the alcohol-based solvent include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, n-decanol, and 3-methoxy-1-butanol, glycol-based solvents such as ethylene glycol, diethylene glycol, and triethylene glycol, and glycol ether-based solvents containing a hydroxyl group, such as ethylene glycol monomethyl ether, propylene glycol monomethyl ether (PGME; also referred to as 1-methoxy-2-propanol), diethylene glycol monomethyl ether, triethylene glycol monoethyl ether, methoxymethyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether, and propylene glycol monophenyl ether. Among these, glycol ether-based solvents are preferably used.

Examples of the ether-based solvent include glycol ether-based solvents having no hydroxyl group, such as propylene glycol dimethyl ether, propylene glycol diethyl ether, diethylene glycol dimethyl ether, and diethylene glycol diethyl ether, aromatic ether solvents such as anisole and phenetole, dioxane, tetrahydrofuran, tetrahydropyran, perfluoro-2-butyltetrahydrofuran, perfluorotetrahydrofuran, and 1,4-dioxane, in addition to the glycol ether-based solvents containing a hydroxyl group. A glycol ether-based solvent or an aromatic ether solvent such as anisole is preferably used.

As the amide-based solvent, for example, N-methyl-2-pyrrolidone, N,N-dimethylacetamide, N,N-dimethylformamide, hexamethylphosphoric triamide, or 1,3-dimethyl-2-imidazolidinone can be used.

Examples of the hydrocarbon-based solvent include aliphatic hydrocarbon-based solvents such as pentane, hexane, octane, decane, 2,2,4-trimethylpentane, 2,2,3-trimethylhexane, perfluorohexane, and perfluoroheptane, and aromatic hydrocarbon-based solvents such as toluene, xylene, ethyl benzene, propyl benzene, 1-methylpropyl benzene, 2-methylpropyl benzene, dimethyl benzene, diethyl benzene, ethylmethyl benzene, trimethyl benzene, ethyldimethyl benzene, and dipropyl benzene. Among these, the aromatic hydrocarbon-based solvents are preferable.

A plurality of the above-described organic solvents may be used in combination, or the solvent may be used in combination with a solvent other than the solvents described above or water. Here, in order to exhibit the effects of the present invention sufficiently, the moisture content of the entirety of the developer is preferably less than 10% by mass, and the developer more preferably substantially does not contain moisture.

The concentration (the total concentration in a case where a plurality of solvents are mixed together) of the organic solvent in the developer is preferably 50% by mass or more, more preferably 70% by mass or more, and still preferably 90% by mass or more. A case where the developer is formed of substantially only an organic solvent is particularly preferable. Moreover, the case where the developer is formed of substantially only an organic solvent is intended to encompass a case where a trace amount of a surfactant, an antioxidant, a stabilizer, an anti-foaming agent, or the like are contained.

Among the solvents, solvents containing one or more selected from the group consisting of butyl acetate, pentyl acetate, isopentyl acetate, propylene glycol monomethyl ether acetate, and anisole are more preferable.

Suitable examples of the organic solvent used as the developer include ester-based solvents.

As the ester-based solvent, a solvent represented by General Formula (S1) which will be described later or a solvent represented by General Formula (S2) which will be described later is more preferably used, the solvent represented by General Formula (S1) is still more preferably used, alkyl acetate is particularly preferably used, and butyl acetate, pentyl acetate, or isopentyl acetate is most preferably used.

R—C(═O)—O—R′ General Formula (S1)

In General Formula (S1), R and R′ each independently represent a hydrogen atom, an alkyl group, a cycloalkyl group, an alkoxyl group, an alkoxycarbonyl group, a carboxyl group, a hydroxyl group, a cyano group, or a halogen atom. R and R′ may be bonded to each other to form a ring.

The alkyl group, the alkoxyl group, or the alkoxycarbonyl group represented by each of R and R′ preferably has 1 to 15 carbon atoms, and the cycloalkyl group represented by each of R and R′ preferably has 3 to 15 carbon atoms.

R and R′ are each preferably a hydrogen atom or an alkyl group, and the alkyl group, the cycloalkyl group, the alkoxyl group, and the alkoxycarbonyl group represented by each of R and R′, and a ring formed by bonding of R and R′ to each other may be substituted with a hydroxyl group, a group including a carbonyl group (for example, an acyl group, an aldehyde group, and alkoxycarbonyl), a cyano group, or the like.

Examples of the solvent represented by General Formula (S1) include methyl acetate, butyl acetate, ethyl acetate, isopropyl acetate, amyl acetate, isoamyl acetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, and ethyl 2-hydroxy propionate.

Among these, a solvent in which R and R′ are each an unsubstituted alkyl group is preferable.

As the solvent represented by General Formula (S1), alkyl acetate is preferable, and butyl acetate, pentyl acetate, or isopentyl acetate is more preferable.

The solvent represented by General Formula (S1) may be used in combination with one or more other kinds of organic solvents. The solvent used in combination in this case is not particularly limited as long as it can be mixed in without being separated from the solvent represented by General Formula (S1), the solvents represented by General Formula (S1) may be used in combination with each other, or a solvent represented by General Formula (S1) may be used by being mixed with a solvent selected from other ester-based solvents, ketone-based solvents, alcohol-based solvents, amide-based solvents, ether-based solvents, and hydrocarbon-based solvents. One or more solvents can be used in combination, but one solvent is preferably used in combination in order to obtain a stable performance. The mixing ratio of the solvent represented by General Formula (Si) to a solvent used in combination in a case where one kind of solvent used in combination is mixed for use is typically 20:80 to 99:1, preferably 50:50 to 97:3, more preferably 60:40 to 95:5, and most preferably 60:40 to 90:10, in terms of a mass ratio.

R″—C(═O)—O—R″—O—R″″ General Formula (S2)

In General Formula (S2),

R″ and R″″ and each independently represent a hydrogen atom, an alkyl group, a cycloalkyl group, an alkoxyl group, an alkoxycarbonyl group, a carboxyl group, a hydroxyl group, a cyano group, or a halogen atom. R″ and R″″ may be bonded to each other to form a ring.

R″ and R″″ are each preferably a hydrogen atom or an alkyl group. The alkyl group, the alkoxyl group, or the alkoxycarbonyl group represented by each of R″ and R″″ preferably has 1 to 15 carbon atoms, and the cycloalkyl group represented by each of R″ and R″″ preferably has 3 to 15 carbon atoms.

R′″ represents an alkylene group or a cycloalkylene group. R′″ is preferably an alkylene group. The number of carbon atoms of the alkylene group for R″″ is preferably in a range of 1 to 10. The number of carbon atoms of the cycloalkylene group for R′″ is preferably in a range of 3 to 10.

The alkyl group, the cycloalkyl group, the alkoxyl group, or the alkoxycarbonyl group for each of R″ and R″″, the alkylene group or the cycloalkylene group represented by R′″, and a ring formed by the mutual bonding of R″ and R″″ may be substituted with a hydroxyl group, a group containing a carbonyl group (for example, an acyl group, an aldehyde group, and an alkoxycarbonyl group), a cyano group, or the like.

In General Formula (S2), the alkylene group for R′″ may have an ether bond in the alkylene chain.

Examples of the solvent represented by General Formula (S2) include propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, propylene glycol monoethyl ether acetate, propylene glycol monopropyl ether acetate, methyl-3-methoxypropionate, ethyl-3-methoxypropionate, ethyl-3-ethoxypropionate, propyl-3-methoxypropionate, ethyl methoxyacetate, ethyl ethoxyacetate, 2-methoxybutyl acetate, 3-methoxybutyl acetate, 4-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, and 4-methyl-4-methoxypentyl acetate, and propylene glycol monomethyl ether acetate is preferable.

Among these, it is preferable that R″ and R″″ are each an unsubstituted alkyl group, and R′″ is an unsubstituted alkylene group, it is more preferable that R″ and R″″ are each either a methyl group or an ethyl group, and it is still more preferable that R″ and R″″ are each a methyl group.

The solvent represented by General Formula (S2) may be used in combination with one or more kinds of other organic solvents. The solvent used in combination in this case is not particularly limited as long as it can be mixed in without being separating from the solvent represented by General Formula (S2), the solvents represented by General Formula (S2) may be used in combination with each other, or a solvent represented by General Formula (S2) may be used by being mixed with a solvent selected from other ester-based solvents, ketone-based solvents, alcohol-based solvents, amide-based solvents, ether-based solvents, and hydrocarbon-based solvents. One or more solvents can be used in combination, but one solvent is preferably used in combination in order to obtain a stable performance. The mixing ratio of the solvent represented by General Formula (S2) to a solvent used in combination in a case where one kind of solvent used in combination is mixed for use is usually 20:80 to 99:1, preferably 50:50 to 97:3, more preferably 60:40 to 95:5, and most preferably 60:40 to 90:10, in terms of a mass ratio.

In addition, suitable examples of the organic solvent used as a developer also include an ether-based solvent.

Examples of the usable ether-based solvent include the ether-based solvents described above, and among these, an ether-based solvent including one or more aromatic rings is preferable, a solvent represented by General Formula (S3) is more preferable, and anisole is the most preferable.

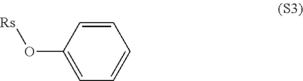

In General Formula (S3),

Rs represents an alkyl group. An alkyl group having 1 to 4 carbon atoms is preferable, a methyl group or an ethyl group is more preferable, and a methyl group is the most preferable.

In the present invention, the moisture content of the developer is usually preferably 10% by mass or less, more preferably 5% by mass or less, and still more preferably 1% by mass or less, and it is the most preferable that the developer contains substantially no moisture.

As the developing method, for example, a method of dipping a substrate in a bath filled with the developer for a fixed time (dip method), a method of raising a developer on a substrate surface by the effect of a surface tension and keeping it still for a fixed time, thereby performing development (puddle method), a method of spraying a developer on a substrate surface (spray method), a method of continuously ejecting a developer on a substrate spinning at a constant speed while scanning a developer ejecting nozzle at a constant rate (dynamic dispense method), or the like can be applied.

Further, after the step of carrying out development, a step of stopping the development by replacing the solvent with another solvent may be practiced.

The development time is not particularly limited as long as it is a period of time for which the resin in the unexposed area is sufficiently dissolved, and usually, the development time is usually 10 seconds to 300 seconds, and preferably 20 seconds to 120 seconds.

The temperature of the developer is preferably 0° C. to 50° C., and more preferably 15° C. to 35° C.

The pattern forming method of the present invention may include a step of washing using a rinsing liquid including an organic solvent after the developing step.

The vapor pressure (the entire vapor pressure in a case of a mixed solvent) of the rinsing liquid used after the organic solvent development is preferably from 0.05 kPa to 5 kPa, more preferably from 0.1 kPa to 5 kPa, and most preferably from 0.12 kPa to 3 kPa, at 20° C. By setting the vapor pressure of the rinsing liquid to from 0.05 kPa to 5 kPa, the temperature uniformity in the wafer plane is enhanced, and further, swelling attributable to permeation of the rinsing liquid is suppressed, and thus, the dimensional uniformity in the wafer plane is improved.

As the rinsing liquid, various organic solvents are used, but a rinsing liquid containing at least one organic solvent selected from a hydrocarbon-based solvent, a ketone-based solvent, an ester-based solvent, an alcohol-based solvent, an amide-based solvent, and an ether-based solvent, or water is preferably used.

More preferably, after the development, a step of performing washing using a rinsing liquid containing at least one organic solvent selected from a ketone-based solvent, an ester-based solvent, an alcohol-based solvent, an amide-based solvent, and a hydrocarbon-based solvent is carried out. Still more preferably, after the development, a step of performing washing using a rinsing liquid containing an alcohol-based solvent or a hydrocarbon-based solvent is carried out.

Particularly preferably, a rinsing liquid containing at least one or more selected from the group consisting of a monohydric alcohol and a hydrocarbon-based solvent is used.

Here, examples of the monohydric alcohol used in the rinsing step after development include a linear, branched, or cyclic monohydric alcohol, and specifically, 1-butanol, 2-butanol, 3-methyl-1-butanol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonal, 9-methyl-2-decanol, or the like can be used. The monohydric alcohol is preferably 1-hexanol, 2-hexanol, 1-pentanol, 3-methyl-1-butanol, 3-methyl-2-pentanol, 3-methyl-3-pentanol, 4-methyl-2-pentanol, or 4-methyl-3-pentanol, and most preferably 1-hexanol or 4-methyl-2-pentanol.

Examples of the hydrocarbon-based solvent include aromatic hydrocarbon-based solvents such as toluene and xylene, and aliphatic hydrocarbon-based solvents such as octane and decane.

The rinsing liquid more preferably contains one or more selected from the group of 1-hexanol, 4-methyl-2-pentanol, and decane.

A plurality of the respective components may be mixed, or the solvent may be mixed with an organic solvent other than those described above before use. The solvent may be mixed with water, but the moisture content in the rinsing liquid is usually 60% by mass or less, preferably 30% by mass or less, more preferably 10% by mass or less, and most preferably 5% by mass or less. By setting the moisture content to 60% by mass or less, good rinsing characteristics can be obtained.

The rinsing liquid can also be used after incorporating an appropriate amount of a surfactant thereinto.

As the surfactant, the same surfactants as those used in the actinic ray-sensitive or radiation-sensitive resin composition which will be described later can be used, and the amount of the surfactant to be used is usually from 0.001% to 5% by mass, preferably from 0.005% to 2% by mass, and more preferably from 0.01% to 0.5% by mass, with respect to the total amount of the rinsing liquid.

In the rinsing step, the developed wafer is subjected to a washing treatment using the above-described rinsing liquid containing an organic solvent.

A method for the washing treatment is not particularly limited, but for example, a method of continuously ejecting a rinsing liquid on a substrate spinning at a constant speed (spin coating method), a method of dipping a substrate in a bath filled with a rinsing liquid for a fixed time (dip method), a method of spraying a rinsing liquid on a substrate surface (spray method), or the like can be applied. Among these, it is preferable to perform a washing treatment by the spin coating method and after the washing, remove the rinsing liquid from the substrate surface by spinning the substrate at a rotation speed of 2,000 to 4,000 rpm.

The rinsing time is not particularly limited, but is usually 10 seconds to 300 seconds, preferably 10 seconds to 180 seconds, and most preferably 20 seconds to 120 seconds.

The temperature of the rinsing liquid is preferably 0° C. to 50° C., and more preferably 15° C. to 35° C.

Furthermore, after the developing treatment or the rinsing treatment, a treatment of removing the developer or the rinsing liquid attached to the pattern by a supercritical fluid can be carried out.

Furthermore, after the development, the rinsing treatment, or the treatment with a supercritical fluid, a heating treatment can be carried out so as to remove the solvent remaining in the pattern. The heating temperature is not particularly limited as long as a good resist pattern is obtained, and is usually 40° C. to 160° C. The heating temperature is preferably 50° C. to 150° C., and most preferably from 50° C. to 110° C. Tue heating time is not particularly limited as long as a good resist pattern is obtained, and is usually 15 seconds to 300 seconds, and preferably 15 to 180 seconds.

### EXAMPLES

Hereinafter, the present invention will be described with reference to Examples in more detail, but the contents of the present invention are not limited thereto.

For the organic/inorganic composite composition, ZR-B, ZR-E, and ZR-H which were each synthesized by the hydrolysis·polycondensation of a metal alkoxide and the reaction of a substance thus formed with a carboxylic acid were used.

ZR-B: Manufactured by KRI Inc., PGMEA solution having a concentration of 2.5% by weight in terms of ZrO₂, aggregated domain size of 2.0 nm, 1.0 mol time the amount of methacrylic acids to be added

ZR-E: Manufactured by KRI Inc., PGMEA solution having a concentration of 2.5% by weight in terms of ZrO₂, aggregated domain size of 2.0 nm, 1.5 mol times the amount of methacrylic acids to be added

ZR-H: Manufactured by KRI Inc., PGMEA solution having a concentration of 2.5% by weight in terms of ZrO₂, aggregated domain size of 2.0 nm, 0.5 mol times the amount of methacrylic acids to be added, 1.0 molar time the amount of butyric acid to be added

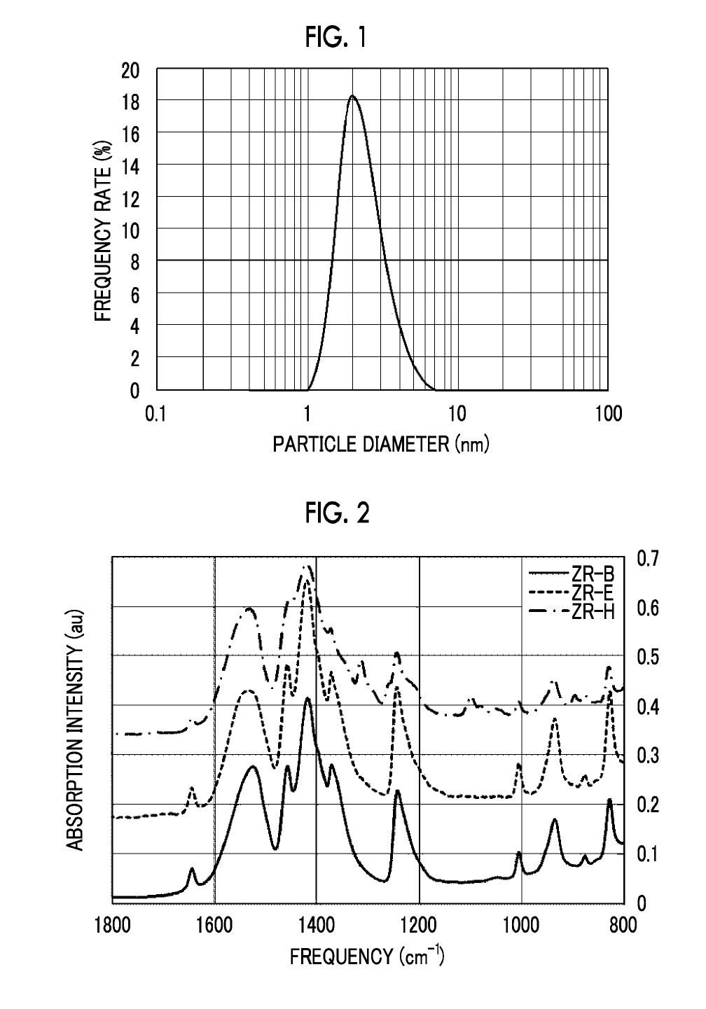

The aggregated domain size indicates a value of the top peak of the particle size distribution data measured by a dynamic light scattering method. For reference, the particle size distribution of ZR-E is shown in FIG. 1.

The infrared absorption spectrum (ATR method) of a film formed using each of the respective composite compositions is shown in FIG. 2. In all the samples, the absorption peaks of free carboxylic acids (in the vicinity of 1,700 cm-1) were not present, and the absorption peaks of the carboxylic acids bonded to the metal ions were observed in the vicinity of 1,550 cm-1 and in the vicinity of 1,420 cm-1 in the chart.

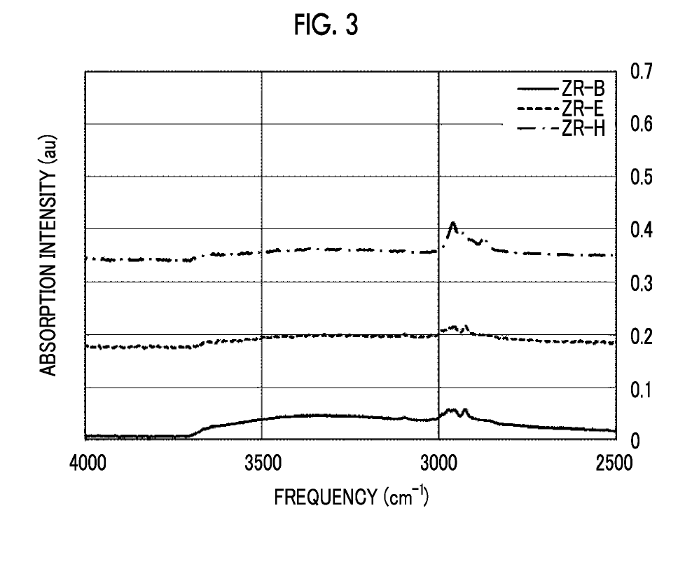

Moreover, as shown in FIG. 3, in ZR-E and ZR-H, absorption of large O-H stretching vibration due to adsorption of hydroxyl groups on the surface and water as observed at 3,000 to 3,600 cm-1 was not substantially found, while in ZR-B, absorption of O-H stretching vibration attributed to adsorbed water was clearly found. This indicates that in ZR-E and ZR-H, hydroxyl groups were not substantially present, and were relatively hydrophobitized.

<Photoacid Generator>

As the compound (Q), (B-1) and (B-2) were prepared.

(B-1) Triphenylsulfonium nonafluorobutanesulfonic acid

(B-2) Triphenylsulfonium trifluoromethanesulfonic acid

<Preparation of Resist Composition>

The components shown in Table 1 were dissolved in propylene glycol monomethyl ether acetate to prepare a solution having the ratios shown in the following table. This solution was filtered using a polytetrafluoroethylene filter or polyvinylidene difluoride filter having a pore size of 0.03 μm to obtain a resist composition. In addition, in Table 1, the amounts of the respective components are in % by mass with respect to the total solid content.

TABLE 1

| | Organic/inorganic | Photoacid | |
|---|---|---|---|
| | composite composition | generator (Q) | Solvent |
| Example | (A) (% by mass) | (% by mass) | (% by mass) |
| Example 1 | ZR-E (5.00) | B-1 (0.25) | PGMEA (94.75) |
| Example 2 | ZR-E (5.00) | B-2 (0.25) | PGMEA (94.75) |
| Example 3 | ZR-E (5.00) | B-1 (0.35) | PGMEA (94.65) |
| Example 4 | ZR-H (5.00) | B-1 (0.25) | PGMEA (94.75) |
| Example 5 | ZR-H (5.00) | B-2 (0.25) | PGMEA (94.75) |
| Example 6 | ZR-H (5.00) | B-1 (0.35) | PGMEA (94.65) |
| Comparative | ZR-E (5.00) | None | PGMEA (95.00) |
| Example 1 | | | |
| Comparative | ZR-H (5.00) | None | PGMEA (95.00) |
| Example 2 | | | |
| Comparative | ZR-B (5.00) | None | PGMEA (95.00) |
| Example 3 | | | |
| Comparative | ZR-B (5.00) | B-1 (0.25) | PGMEA (94.75) |
| Example 4 | | | |

<Manufacture of Resist Evaluation (Manufacture of Coated Film)>

The resist solution was applied onto a silicon substrate (SiO₂/Si) which had been subjected to a surface heat treatment, using a spin coater. The resultant was heated and dried on a hot plate at 100° C. over 60 seconds to obtain a resist film having an average film thickness of 50 nm.

<Evaluation of Resist (Heating and Drying Stability of Coated Film)>

The solubility of the manufactured resist film in a butyl acetate solvent was confirmed immediately after the application (before heating and drying). Since the resist film was of a negative tone type using organic solvent development, it is necessary to dissolve the resist film in a butyl acetate solvent before the manufacture of a coated film and after heating and drying, and a case where the resist film was dissolved without problems was denoted as O and a case where the resist film was not dissolved was denoted as X.

<Resist Evaluation (EB)>

The manufactured resist film was subjected to irradiation with electron beams, using an electron beam irradiation device (F125 manufactured by Elionix Inc.; acceleration voltage of 125 keV). Thereafter, the resist film was developed with a butyl acetate solvent at 23° C. for 30 seconds, and dried, thereby forming a line-and-space pattern (line:space=1:4).

(Sensitivity)

The obtained pattern was observed using a scanning electron microscope (S-9260; manufactured by Hitachi, Ltd.). Further, the exposure dose at a time of exposure of a line having a line width of 20 nm (line:space=1:4) was taken as sensitivity.

(Residuals)

When the pattern formability was observed with a scanning electron microscope in order to perform the evaluation for sensitivity measurement, a space portion and the boundary portion of a line were carefully observed, and it was confirmed by visual observation whether the residuals were generated.

A case where there were no residuals was denoted as O and a case where there were residuals was denoted as X.

TABLE 2

| | Heating | | | |
|---|---|---|---|---|
| | and drying | Heating drying | | |
| | stability of | stability of | | |
| | coated film | coated film | Sensitivity | |
| Example | (before drying) | (after drying) | (μC/cm²) | Residuals |
| Example 1 | ◯ | ◯ | 8 | ◯ |
| Example 2 | ◯ | ◯ | 9 | ◯ |
| Example 3 | ◯ | ◯ | 7 | ◯ |
| Example 4 | ◯ | ◯ | 11 | ◯ |
| Example 5 | ◯ | ◯ | 12 | ◯ |
| Example 6 | ◯ | ◯ | 10 | ◯ |
| Comparative | ◯ | ◯ | 25 | X |
| Example 1 | | | | |
| Comparative | ◯ | ◯ | 30 | X |
| Example 2 | | | | |
| Comparative | X | X | Image not | Image not |
| Example 3 | | | formed | formed |
| Comparative | X | X | Image not | Image not |
| Example 4 | | | formed | formed |

As shown in Table 2, the compositions of Examples exerted excellent performance, as compared with the compositions of Comparative Examples.

What is claimed is:

1. An actinic ray-sensitive or radiation-sensitive composition comprising:
(A) a compound in which in hydrolysis polycondensation of a metal alkoxide containing a metal or metalloid element, the aggregated domain size of the metal or metalloid element is 1 to 5 nm, and 1.2 to 2.0 mol times of a carboxylic acid and/or a carboxylic acid derivative with respect to the metal or metalloid element exists, and forms a coordinated structure;
(B) a compound capable of generating an acid upon irradiation with actinic rays or radiation; and
(C) an organic solvent.

2. The composition according to claim 1, which is used for pattern formation by EUV exposure.

3. The composition according to claim 1, which is used for pattern formation by irradiation with electron beams or X-rays.
